(19) United States
(12) Patent Application Publication
(10) Pub. No.: US 2014/0350877 A1
(43) Pub. Date: Nov. 27, 2014

(54) BATTERY PARAMETERS, STATE OF CHARGE (SOC), AND STATE OF HEALTH (SOH) CO-ESTIMATION

(71) Applicant: North Carolina State University, Raleigh, NC (US)

(72) Inventors: Mo-Yuen Chow, Cary, NC (US); Habiballah Rahimi Eichi, Raleigh, NC (US)

(73) Assignee: North Carolina State University, Raleigh, NC (US)

(21) Appl. No.: 14/285,853

(22) Filed: May 23, 2014

Related U.S. Application Data
(60) Provisional application No. 61/827,586, filed on May 25, 2013.

(51) Int. Cl. G01R 31/36

(52) U.S. Cl. CPC G01R 31/3637
USPC 702/63

(57) ABSTRACT

Battery parameters, state of charge, and state of health co-estimation are disclosed. According to an aspect, a method includes determining a terminal current and a terminal voltage of a battery. The method also includes maintaining a battery model that defines a relationship between a parameter of the battery, the terminal current, and the terminal voltage. Further, the method includes determining the parameter of the battery based on the battery model and the acquired terminal current and the terminal voltage.

### CROSS REFERENCE TO RELATED APPLICATION

This application claims the benefit of and priority to U.S. Provisional Patent Application No. 61/827,586, filed May 25, 2013 and titled BATTERY PARAMETERS, STATE OF CHARGE (SOC), AND STATE OF HEALTH (SOH) CO-ESTIMATION, the content of which is hereby incorporated herein by reference in its entirety.

### FEDERALLY SPONSORED RESEARCH OR DEVELOPMENT

The technology disclosed herein was made with government support under grant number EEC-08212121 awarded by the National Science Foundation (NSF). The United States government may have certain rights in the technology.

### TECHNICAL FIELD

The present subject matter relates to battery parameters, state of charge (SOC), and state of health (SOH) co-estimation.

### BACKGROUND

Advanced battery technology serves electric vehicles industry with employing different chemistries and assembling techniques to provide higher power and energy density. Nonetheless, the mere utilization of these technologies does not guarantee the efficiency, safety and reliability of the battery function. To ensure these features, the battery's status needs to be accurately monitored and controlled by the algorithms that are designed to perform battery management system (BMS). The total capacity is one of the most crucial characteristics of the battery that needs to be monitored. All of the methods that rely on the coulomb counting to estimate the State of Charge (SOC) need to have an accurate estimation of the total capacity. Moreover, the full capacity and its degradation due to aging is a prominent indicator to determine the State of Health (SOH) of the battery. Other than aging in the form of cycling or storage aging, the ambient temperature can also cause capacity fading that makes the total capacity of the battery different from the nominal capacity.

Future advanced transportation systems via Plug-In Hybrid Electric Vehicles (PHEV) and Plug-In Electric Vehicles (PEV) may not be feasible without significant improvements in battery technology and battery management system. Moreover, a battery is a critical component in the infrastructure of the rapidly evolving smart grid. In addition to efficiency and reliability, which mostly depends on the battery technology, an accurate monitoring of the battery status information is essential for an effective power management of a smart grid. Battery status information includes SOC and SOH. Battery SOC may be defined as the percentage of the charge left in the battery divided by the battery rated capacity. Battery SOH is a factor to evaluate the ability of the battery to repeatedly provide its rated capacity over time. Several approaches have been proposed to estimate the SOC and SOH of a battery. These estimation approaches are mostly based on a dynamic model of the battery. Thus, a more precise battery modeling can result in a more accurate state estimation.

According to the accuracy and application, different types of battery models have been developed. Electrochemical models use complex electrochemical equations to describe microscopic and macroscopic behaviors of the battery. Since these equations mostly need computational and time-consuming techniques to be solved, they are more appropriate for battery design optimization processes. Mathematical models are other tools to describe the dynamics of the battery using statistical and empirical data. These models are more appropriate to predict efficiency or capacity of the battery and are not able to give an explicit relationship between current, voltage, and temperature (measurable values of the battery) for simulation. Moreover, the mathematical models are not very accurate and usually come with 5-20% error.

For at least the aforementioned reasons, there is a need for improved systems and techniques for estimating battery parameters and functionality.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Battery parameters, state of charge, and state of health co-estimation are disclosed herein. According to an aspect, a method includes determining a terminal current and terminal voltage of a battery. The method also includes maintaining a battery model that defines a relationship between a parameter of the battery, the terminal current, and the terminal voltage. Further, the method includes determining the parameter of the battery based on the battery model and the acquired terminal current and terminal voltage.

### BRIEF DESCRIPTION OF THE DRAWINGS

The foregoing summary, as well as the following detailed description of various embodiments, is better understood when read in conjunction with the appended drawings. For the purposes of illustration, there is shown in the drawings exemplary embodiments; however, the presently disclosed subject matter is not limited to the specific methods and instrumentalities disclosed. In the drawings:

FIG. 1 is a circuit diagram of a combined battery model with relaxation effect, internal resistance, and V_{OC}-SOC function;

FIG. 2 is a graph of an actual V_{OC}-SOC curve of the Li-polymer battery;

FIGS. 3A and 3B depict graphs of a first and second derivative, respectively, of V_{OC} versus SOC;

FIG. 4 is a graph of piecewise linear mapping of V_{OC}-SOC curve;

FIG. 5 is a circuit diagram of a battery-equivalent circuit;

FIG. 6 is a diagram of an observer structure;

FIG. 7 is a schematic diagram of an experimental set-up;

FIG. 8 depicts graphs of current and voltage of the battery;

FIGS. 9A-9D depict graphs of online identified battery parameters;

FIG. 10 is a diagram of b₀-b₁ relationship block diagram;

FIG. 11 is a graph of SOC estimation result from the updating observer;

FIG. 12 is a graph of SOC estimation error;

FIG. 13 is a block diagram that demonstrates the battery parameters/SOC co-estimation algorithm in accordance with embodiments of the present disclosure;

FIG. 14 is a block diagram that implements the battery capacity observer to estimate the battery capacity;

FIGS. 15A and 15B show graphs of current and voltage data obtained from the battery model;

FIGS. 16A-16D shows graphs of a comparison of the parameters identification results for nominal and updated capacity nominal and actual capacities;

FIG. 17 shows a graph of a comparison of SOC estimations with nominal and updated capacity;

FIG. 18 is a graph showing capacity estimation compared to the actual capacity of the battery;

FIGS. 19A-19D are graphs showing a comparison of the parameters identification results for the actual and the degraded capacity on the experimental data;

FIG. 20 is a graph showing a comparison of SOC estimations with nominal and degraded capacity for the experimental data; and

FIG. 21 is a graph showing estimated capacity compared to the nominal (actual) capacity for the experimental data.

### DETAILED DESCRIPTION

The presently disclosed subject matter is described with specificity to meet statutory requirements. However, the description itself is not intended to limit the scope of this patent. Rather, the inventors have contemplated that the claimed subject matter might also be embodied in other ways, to include different steps or elements similar to the ones described in this document, in conjunction with other present or future technologies.

Disclosed herein are electrical models and resistor-capacitor (RC) equivalent circuits for representing the dynamics of the battery more accurately. These models can be easy to implement and use low computational time and memory to be implemented. Optimal modeling for each battery and each particular application may be a trade-off between accuracy of the model and complexity and the order of the battery equations.

Despite the intrinsic nonlinear behavior of the battery, mainly caused by V_{OC}-SOC nonlinear function, a piecewise linear model for a battery is disclosed. Due to the strong background theory for linear systems and convenient design tools, design and analysis in the linear area is a significant benefit. On the other hand, considering the V_{OC}-SOC curve of the lithium polymer battery obtained from experimental tests makes the piecewise linear approximation of the V_{OC}-SOC function reasonable. This verification is discussed further herein. Therefore, considering a piecewise linear relationship between V_{OC} and SOC, the battery model can be presented as a linear system transfer function with step-wise varying parameters. This structure may be appropriate to apply an online parameter identification algorithm to estimate the parameters of the system that are changing with SOC. Identified herein are parameters of the linear system using a moving window least-squares (LS) identification method. Afterwards, the identified parameters can be used to update the parameters of the observer structure to estimate the SOC of the battery.

### Battery Modeling

In accordance with embodiments, equivalent circuits, systems, and methods are disclosed herein for modeling the dynamics of batteries. Based on the expected accuracy, different components can be added to the model to represent various characteristics of a battery. On the other side, embedding several components into the model can create a large amount of complexity and a system with a higher order. Therefore, considering the details in the model is a trade-off between accuracy and complexity. Described herein are some of the battery characteristics that can be used in the battery model for the present disclosure.

A. Linear Model with Internal Resistance

A typical battery can be modeled by a large capacitor. The capacitor can store a large amount of electrical energy in the charging mode and release it during discharging mode. Since charging/discharging is a chemical process with electrolyte and inter-phase resistance, a small resistor, R, can be used in series with a capacitor, C, for modeling. This small resistor can be referred to as the internal resistor of the battery and can change with the state of charge, the ambient temperature, and the aging effect of the battery.

### B. Relaxation Effect

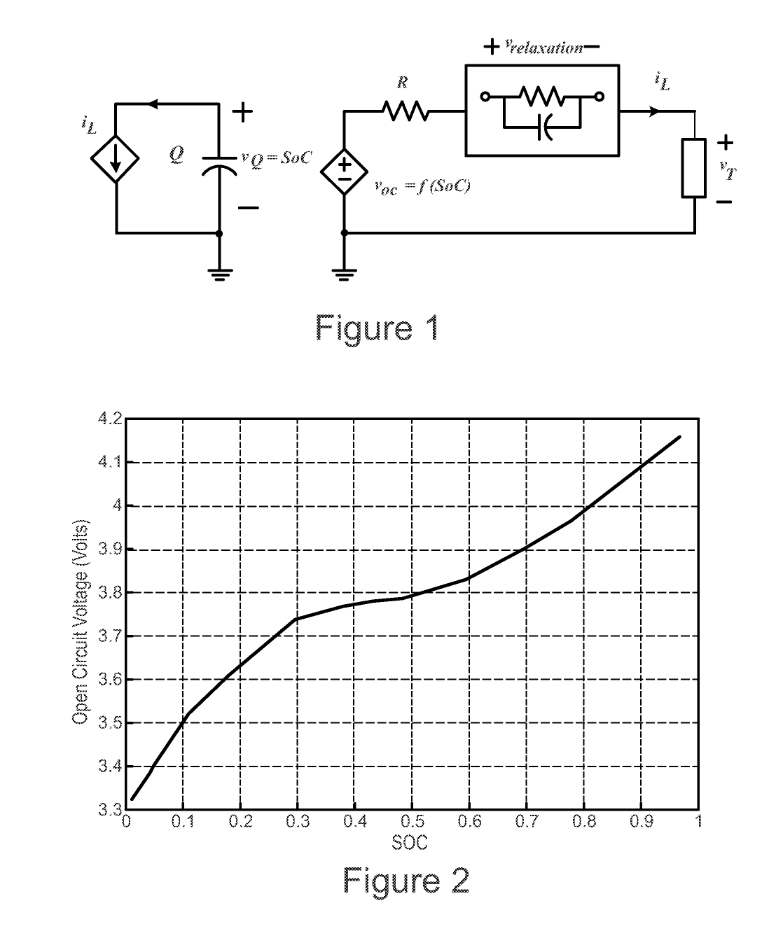

Relaxation effect is another fundamental battery characteristic that emerges in the cycles of charging and discharging. This effect represents the slow convergence of the battery open circuit voltage (V_{OC}) to its equilibrium point after hours of relaxation following charging/discharging. Relaxation effect is a phenomenon caused by diffusion effect and double layer charging/discharging effect. This characteristic is modeled by series-connected parallel RC circuits. Regarding the trade-off between accuracy and complexity, a different number of RC groups can be considered in the equivalent model. FIG. 1 shows the equivalent circuit for an example model that including the relaxation effect. More particularly, FIG. 1 shows a combined battery model with relaxation effect, internal resistance, and V_{OC}-SOC function. Moreover, another difference between this model and the linear model is that this model has a controlled voltage source to include the nonlinear relationship between open circuit voltage and the state of charge.

C. V_{OC}-SOC relationship

The V_{OC}-SOC relationship is a static characteristic of a battery under predetermined conditions of temperature and age. To model this nonlinear part of the battery, several nonlinear equation may be used. Some of the equations relating thereto also consider the hysteresis effect of the battery. The hysteresis effect can cause the discharging curve to stay below the charging curve for the same amount of SOC. Although the proposed models for the V_{OC}-SOC function are comprehensive, fitting the experimental V_{OC}-SOC curve to the equations results in modeling errors. Moreover, the nonlinearity of the model can increase the complexity of the analysis regarding stability and performance of the estimators. Therefore, considering the V_{OC}-SOC curve of the lithium polymer battery from experimental results, shown in FIG. 2 (which shows the actual V_{OC}-SOC curve of the Li-polymer battery), it provides the notion that it can be divided into several linear regions. The first and the second derivative of the V_{OC} versus SOC can be used to find out if a proper finite linear segments can be found for the V_{OC}-SOC curve. The first derivative

$$( \frac{\partial {V}_{OC}}{\partial SOC} )$$

and the second one

$$( \frac{{\partial }^{2} ( {V}_{OC} )}{{( \partial ( SOC ) )}^{2}} )$$

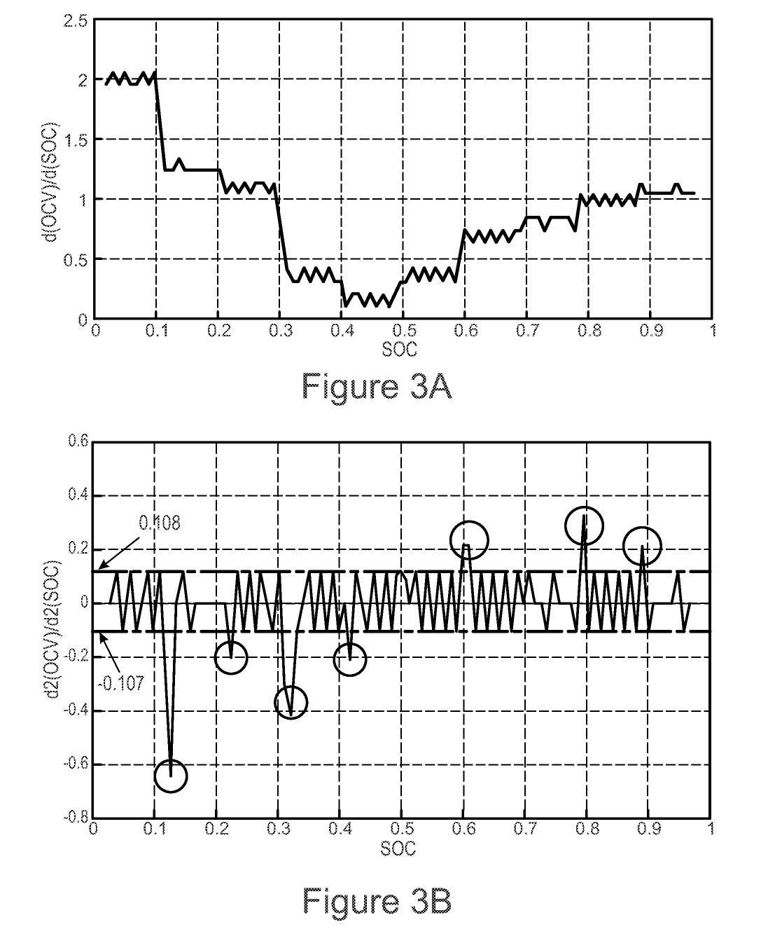

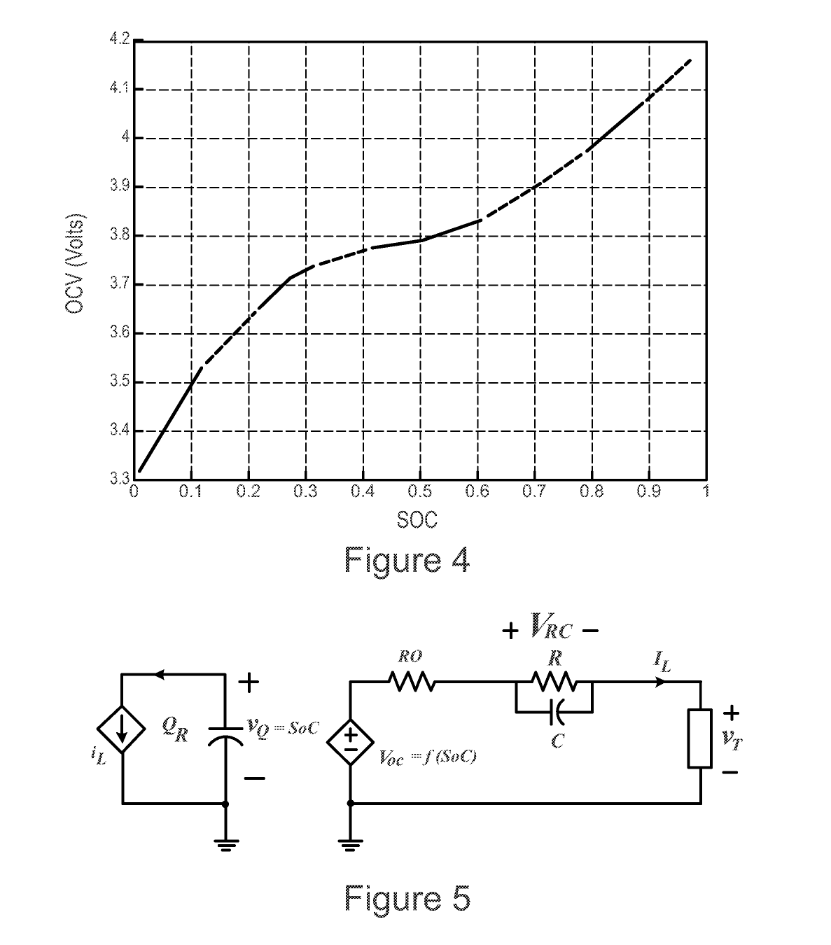

are displayed in FIGS. 3A and 3B, respectively. More particularly, FIGS. 3A and 3B show the first and the second derivative, respectively, of V_{OC} versus SOC. FIG. 3B shows that most of the second derivative values are within the small interval of [-0.107, 0.108] and a few (exactly 7) points stand out of this region. They can be considered as the cross points to divide the curve into linear segments. Therefore, as shown in FIG. 4, the V_{OC}-SOC curve is approximated by 8 segments, and each of them may be described by the following linear equation:

V_{oc}=f(SOC)=b₀+b₁SOC. (1)

Using a least square error curve fitting technique, the values for b₀ and b₁ and the goodness of fit evaluation factor, R², can be derived for each segment. The results, presented in Table I below, shows that b₁ which is the slope of the mapping line starts from a large value of 1.97 for SOC <0.11, gradually decreases to the smallest value of 0.3 on the 5^{th} segment and afterwards increases to 1.05 for SOC >0.89. Moreover, the fitting criteria, R², indicates that segment 5 (0.4<SOC <0.6) has the worst fitting factor compared to the other segments. Segment 4 has the next worst fitting criteria; while the first and the last segments are the best fitted ones.

TABLE I
Parameters and fitness of piecewise linear segments

| | Param. | | |
|---|---|---|---|
| Seg. | b₀ | b₁ | R² |
| 1 | 3.3046 | 1.9702 | 0.9991 |
| 2 | 3.3861 | 1.2348 | 0.9997 |
| 3 | 3.4299 | 1.0337 | 0.9945 |
| 4 | 3.6407 | 0.3389 | 0.9933 |
| 5 | 3.6479 | 0.3014 | 0.9667 |
| 6 | 3.3746 | 0.7604 | 0.9979 |
| 7 | 3.1981 | 0.9892 | 0.9998 |
| 8 | 3.1442 | 1.0509 | 0.9999 |

### D. State-Space Equations for the Model

To model the battery characteristics, an equivalent circuit is used like that of FIG. 5 with one RC group to represent the relaxation effect. Although two RC groups may be used as the optimal trade-off between accuracy and complexity of the model, alternatively one RC group structure can provide sufficiently accurate results for a short time duration (e.g., seconds to minutes) prediction such as the applications in PHEV and PEV. Therefore, this model may be utilized to reduce the complexity of the model identification and the parameter extraction. Moreover, as we discussed earlier the V_{OC} vs. SOC function is mapped to several piecewise linear equations with the form of equation (1). Considering the equivalent circuit for the battery model in FIG. 5, the state-space equations can be written as system (2) to represent the battery dynamics. In these equations, the SOC of the battery, and the voltage across the RC cell, V_{RC}, are selected to be system state variables.

$$\{ \begin{matrix}[ \begin{matrix}\dot{S O C} \\ \dot{{V}_{RC}}\end{matrix} ] = [ \begin{matrix}0 & 0 \\ 0 & - \frac{1}{RC}\end{matrix} ] [ \begin{matrix}S O C \\ {V}_{RC}\end{matrix} ] + [ \begin{matrix}1 / {Q}_{R} \\ 1 / C\end{matrix} ] {I}_{L} \\ {V}_{T} = [ \begin{matrix}{b}_{1} & 1\end{matrix} ] [ \begin{matrix}S O C \\ {V}_{RC}\end{matrix} ] + {R}_{0} {I}_{L} + {b}_{0}\end{matrix} . \qquad ( 2 )$$

Herein, it is assumed that the terminal current (I_{L}) and voltage (V_{T}) are the only two values that are accessible from system (2). Herein, the temperature effect and the capacity fading are not considered to be caused by aging of the battery. To obtain the estimated SOC as one of the states, the parameters in system (2) need to be identified. Apparently, Q_{R} is known to be the nominal capacity of the battery. So, {b₀, R, C, R₀, b₁, S_{oc},V_{RC}} can be estimated as {\hat{b}₀, \hat{R}, Ĉ, \hat{R}₀, \hat{b}₁, Ŝ_{oc}, \hat{V}_{RC}} using system parameter identification methods and state estimation.

### System Parameter Identification and State Estimation

### A. Least-Squares (LS) and Recursive Least-Squares Parameter (RLS) Identification

In order to identify the parameters of a linear time-invariant (LTI) system, the relationship between the system input/output (I/O) samples can be described by a standard structure, such as the autoregressive exogenous model (ARX model):

A(q)y(q)=B(q)u(q)+e(q), (3)

in which,

A(q)=1+a₁q⁻¹+ . . . +aₙq⁻ⁿ, (4)

B(q)=b₀+b₁q⁻¹+ . . . +bₘq^{-m}, (5)

and e(q) is a zero mean Gaussian white noise. Therefore, with this model the output at the present step can be estimated by the input and output values at previous steps. Least Square (LS) identification approach provides a formula to minimize the least-square error between this estimated output value and the real output at present step. Since the input-output samples can be updated step-by-step while the system is running, the Recursive Least Square (RLS) is used to estimate the parameters of the system iteratively. Due to the fact that implementing the RLS algorithm is not easy in a real system and the I/O signal needs to be persistently exciting (PE) at each step, the moving-window LS method may be used, and this method is more practical. In this approach, the I/O data corresponding to a certain number of (window) past steps is used to estimate the parameters. The length of the window depends on the excitation of the input signal to properly reveal the dynamics of the system.

### B. Battery Parameter Identification

The parameters of the battery model needed to be estimated may include: {b₀, R, C, R₀, b₁}. Since most of the parameter identification methods use the transfer function of the system to identify the parameters, first the transfer function form of system (2) is obtained:

$$\frac{Y ( s ) - {b}_{0}}{U ( s )} = \frac{{R}_{0} {s}^{2} + ( \frac{{b}_{1}}{{Q}_{R}} + \frac{1}{C} + \frac{{R}_{0}}{RC} ) s + \frac{{b}_{1}}{{RCQ}_{R}}}{s ( s + \frac{1}{RC} )} , \qquad ( 5 )$$

From transfer function (16) and using bilinear transform

$$( s -> \frac{2}{T} \frac{z - 1}{z + 1} ) ,$$

the discrete transfer function of system (2) with sample time T can be obtained:

$$\frac{Y ( {z}^{- 1} ) - {b}_{0}}{U ( {z}^{- 1} )} = \frac{{c}_{0} + {c}_{1} {z}^{- 1} + {c}_{2} {z}^{- 2}}{1 + {a}_{1} {z}^{- 1} + {a}_{2} {z}^{- 2}} , \qquad ( 6 )$$

where:

$$\begin{matrix}{c}_{0} = \frac{{T}^{2} {b}_{1} + 2 {Q}_{R} {R}_{0} T + 2 {Q}_{R} RT + 4 {Q}_{R} {R}_{0} RC + 2 {b}_{1} RCT}{2 {Q}_{R} T + 4 {Q}_{R} RC} , & ( 7 a ) \\ {c}_{1} = \frac{{T}^{2} {b}_{1} - 4 {Q}_{R} {R}_{0} RC}{{Q}_{R} T + 2 {Q}_{R} RC} , & ( 8 b ) \\ {c}_{2} = \frac{{T}^{2} {b}_{1} - 2 {Q}_{R} {R}_{0} T - 2 {Q}_{R} RT + 4 {Q}_{R} {R}_{0} RC - 2 {b}_{1} RCT}{2 {Q}_{R} T + 4 {Q}_{R} RC} , & ( 8 c ) \\ {a}_{1} = \frac{- 8 {Q}_{R} RC}{2 {Q}_{R} T + 4 {Q}_{R} RC} , & ( 8 d ) \\ {a}_{2} = \frac{- 2 {Q}_{R} T + 4 {Q}_{R} RC}{2 {Q}_{R} T + 4 {Q}_{R} RC} . & ( 8 e )\end{matrix}$$

According to equations (7) and (8), the time-domain relationship between different samples of input and output is as follows:

y(k)=−a₁y(k−1)−a₂y(k−2)+b₀(1+a₁+a₂)+c₀u(k)+c₁u(k−1)+c₂u(k−2). (9)

Equations (8d) and (8e) imply that:

1+a₁+a₂=0, (10)

which means that the value of b₀ does not affect the estimation of the current output y(k), and subsequently, the other parameters. In other words, b₀ acts like an output offset that does not influence the dynamic between input and output. Therefore, solving equations (8a-e) can be shown to give a unique expression of the battery parameters versus the coefficients of the transfer function (7).

### C. Observer Design

After identifying the parameters of the battery, an observer may be designed to estimate the SOC, which is one of the states of the model. The observer can compare the real output to the estimated output of the model with the identified parameters. Then, it compensates for the error, caused by uncertainties and initial values, by giving a proper feedback to the states via a designed gain (observer gain).

Thus, in this stage the battery parameters {R, C, R₀, b₁, b₀} are assumed to be estimated as{\hat{R},Ĉ, \hat{R}₀, \hat{b}₁, \hat{b}₀}. Moreover, the battery model is represented as a system with equations (11):

$$\{ \begin{matrix}\dot{x} = Ax + Bu \\ y = Cx + Du + {b}_{0}\end{matrix} \qquad ( 11 )$$

in which, x₁=S_{oc}, x₂=V_{RC},

$$A = [ \begin{matrix}0 & 0 \\ 0 & - \frac{1}{RC}\end{matrix} ] , B = [ \begin{matrix}1 / {Q}_{R} \\ 1 / C\end{matrix} ] ,$$

C=[b b₁ 1], D=R₀, u=I_{L}, y=V_{T},

$$x = [ \begin{matrix}{x}_{1} \\ {x}_{2}\end{matrix} ] .$$

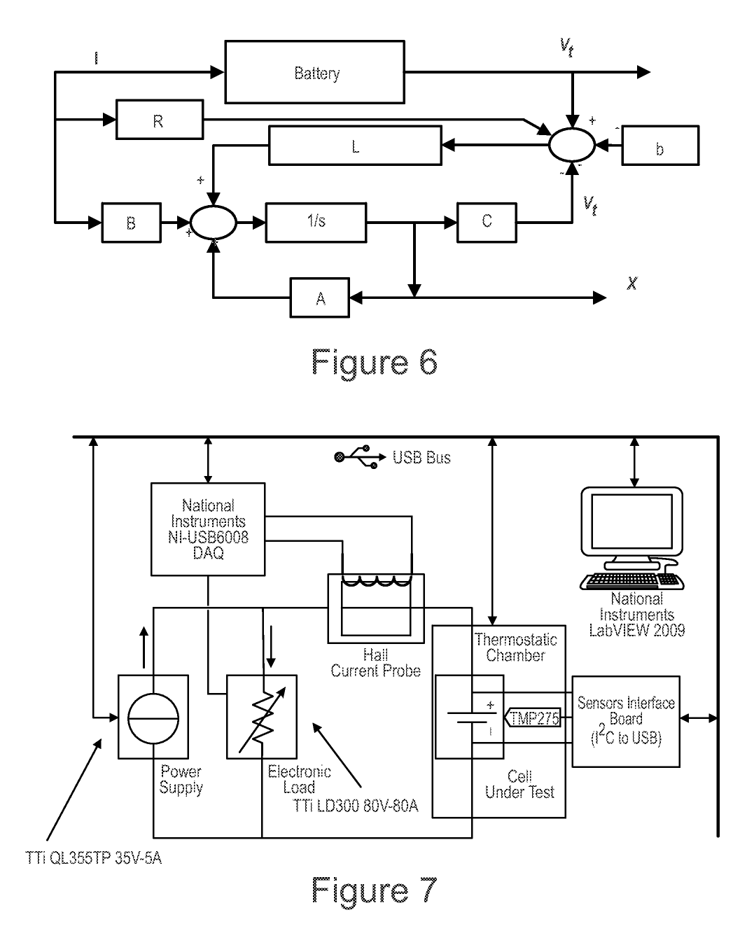

Therefore, the observer can be designed as a system with equations (12):

$$\{ \begin{matrix}\dot{\hat{x}} = A \hat{x} + Bu + L ( y - \hat{y} ) \\ \hat{y} = C \hat{x} + Du + {b}_{0}\end{matrix} \qquad ( 12 )$$

in which L^{T}=[L₁ L₂] is the observer gain vector, and other arguments have the same dimensions as the corresponding arguments in system (11). From Equation (12), it can be seen that even though R, C, R₀ and b₁ are estimated accurately, there is no standard method of identifying b₀. A piecewise linear approximation for the V_{OC}-SOC curve may be utilized. Subsequently, a look-up table may be used to estimate b₀ based on the identified b₁.According to the experimental V_{OC}-SOC curve, piecewise linearization is not an accurate assumption for the battery. Therefore, another approach may be used in which a reduced-order observer is provided to estimate the SOC. With accurate identification of R, C, and R₀, the voltage across the RC group, VRC, and the voltage drop on the internal resistance R₀iL, can properly be estimated without using an observer. That is because the observer is basically used to compensate for the errors caused by initial values or uncertainties and in the case of V_{RC}, with negligible uncertainties. It can be shown that the dynamic of V_{RC} can compensate for the error caused by the initial value in a few pulses. Therefore, as shown in FIG. 6, the V_{OC} can be calculated by substracting VRC and R₀iL from the terminal voltage v_{T}. Subsequently, using VOC as the output of the reduced-order battery system, the observer equation is

$$SOC = \frac{1}{{Q}_{R}} + {i}_{L} + L ( f ( SOC ) - {V}_{OC} )$$

in which f(SOC) is the is the experimental look-up table for V_{OC}-SOC relationship and L is the single-dimension observer gain. This observer structure with a proper gain can compensate the initial value and uncertainty error for SOC estimation.

FIG. 6 shows the block diagram of the observer. In this diagram, the estimated terminal voltage can be calculated by applying input, I_{L}, to a dynamic model with state space matrices of A, B, C and R₀ as D. Adding b₀ as an offset, this estimated out can be subtracted from the real terminal voltage of the battery to provide the error signal. This signal is magnified by the observer gain, L, to obtain the feedback to the estimated states of the battery.

### Battery Tests

Actual experiments have been carried out on lithium-polymer cells to validate the above described method. The lithium-polymer battery technology was selected because of its very high energy and power densities. These characteristics, along with other positive aspects, such as the very low self-discharge rate (around 3% per month) and the very high charge/discharge efficiency, common to other lithium-ion battery technologies, make this technology very attractive for improving the performance and the driving range of PHEVs and PEVs.

The tests were performed on 1.5 Ah lithium-polymer cells using the experimental set-up sketched in FIG. 7, which is a schematic diagram of the experimental set-up. The cell under test is placed inside a custom temperature-controlled chamber, so that the cell temperature can be kept at given value during a test. As shown in FIG. 7, a power supply and an electronic load to be charged and discharged at the desired current. The cell voltage and current are measured by a 16-bit ADC and an Agilent 1146A 100 kHz/100A AC/DC Hall current probe respectively. All the instruments are connected to a computer and managed by an application developed in LabVIEW graphical programming environment.

The cells (Kokam SLPB723870H4) used in the tests can continuously be charged and discharged within the 2.7 V and 4.2 V voltage range with currents up to 3 A and 30 A respectively. All the performed tests have the same structure, including an Init Phase, a Pause Phase and a Test Phase. During the Init Phase the cell is completely charged (continuous-current followed by continuous-voltage mode) and then, after one hour pause, is completely discharged, with the current of 1.5 A. During the Pause (one hour) the cell settles down ensuring that all the transients subside before starting the real test (Test Phase), which will thus start from a well-known status. A significant example of the Test Phase is the pulsed charge/discharge cycle, which makes it possible to extract valuable characteristics of the cell under test. In particular, if the behavior of the cell terminal voltage during the zero current intervals is considered, and it is fitted with an exponential function, the open circuit voltage at the state of charge given by the coulomb counting of the measured cell current is given by the final value of the exponential fitting. This method was applied to derive the V_{OC}-SOC curve depicted in FIG. 2. For this purpose, each current pulse determined a 1% SOC variation and the following zero current interval lasted 5 minutes. In fact, two V_{OC}-SOC curves may be extracted, one during the charging phase and the other during the sequent discharging phase. A small difference can be observed between the two curves, confirming that the hysteresis effect is not so evident for lithium-polymer technology, as it is for the LiFePO4 lithium-ion chemistry. The curve reported in FIG. 3 is the average between the charge and discharge V_{OC}-SOC curves.

### Results and Discussion

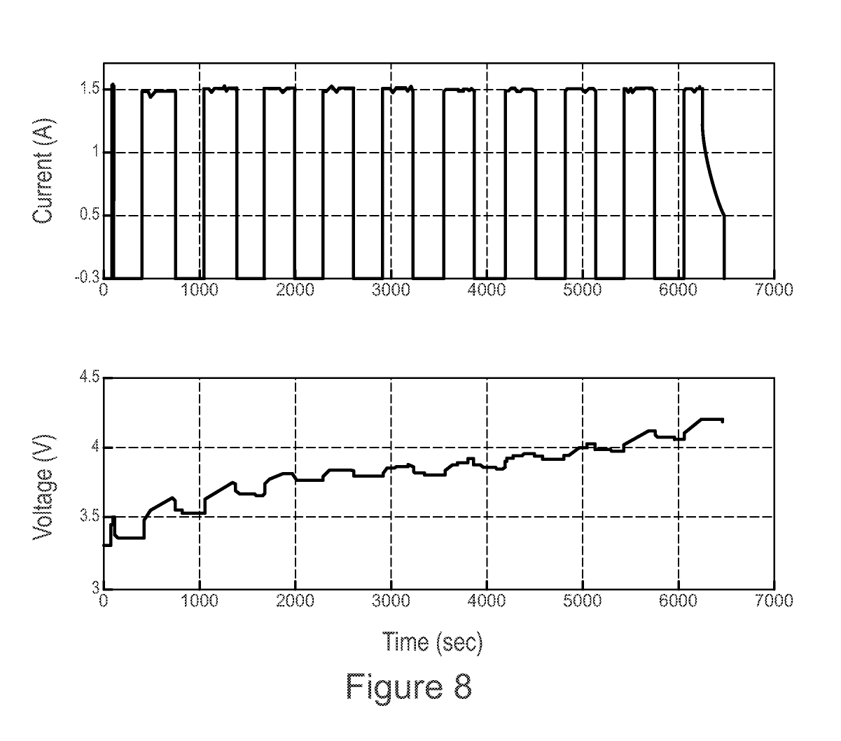

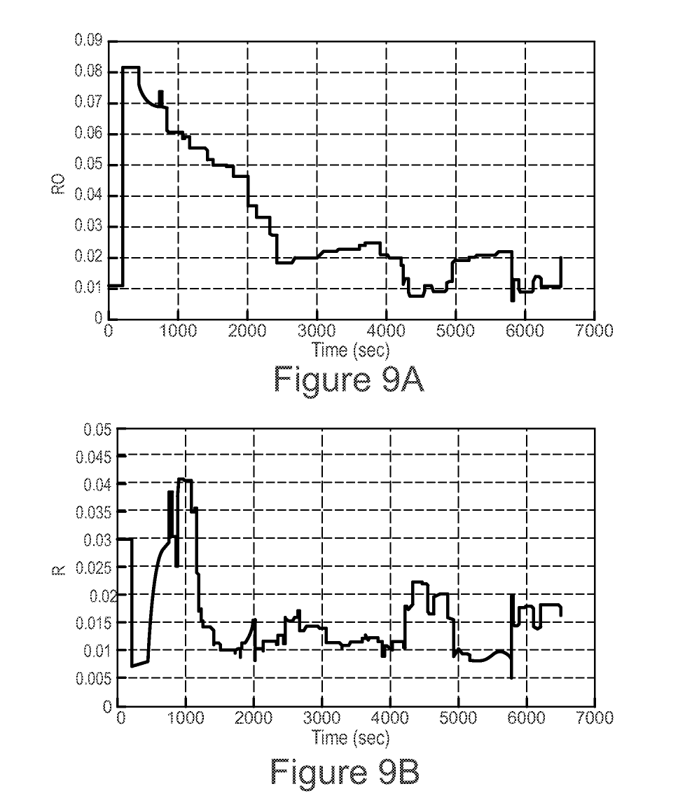

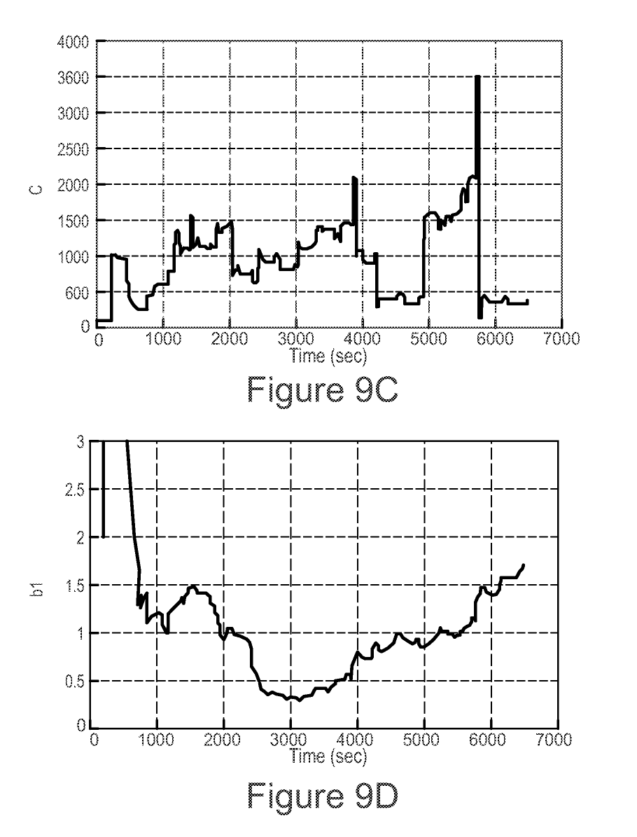

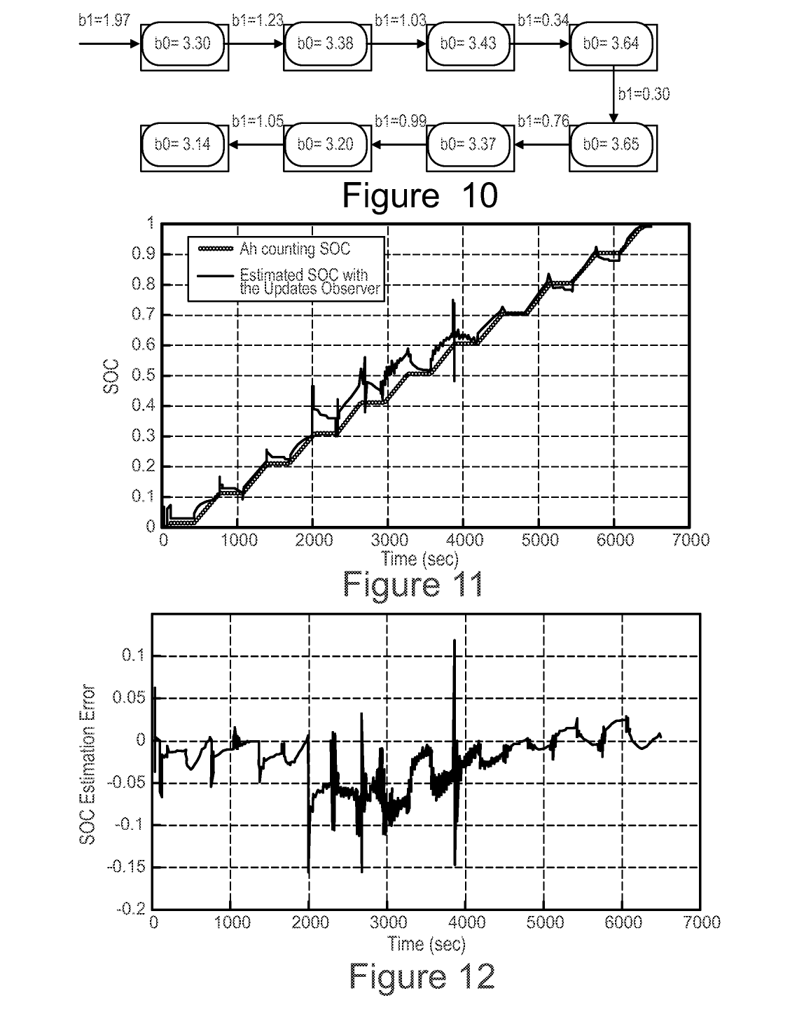

The data acquired during the experimental tests are used to evaluate the accuracy of the piecewise linear model for the battery, the online parameter identification algorithm, and the state estimation method. FIG. 8 shows the terminal current and voltage of the battery during a pulse charging of the Li-Polymer battery. These data are used as the input-output data to the moving window least square parameter identification algorithm. Since a step pulse is applied to the battery every 10 minutes (600 seconds), the moving window cannot be smaller than 300 seconds to at least include one of the pulse edges. The results for identification of the battery parameters are displayed in FIGS. 9A-9D. It can be observed that in this type of battery R₀, R and C change a lot with SOC. As expected, the value for the internal resistance, R₀, is large for small SOCs and decreases when SOC increases. This frequent change verifies the essential need for online parameter identification at least in this type of battery. Moreover, the values for b₁ in FIG. 9D follow the expected profile for b₁ in Table I for a charging cycle. The relationship between b₁ and b₀, obtained from Table I, is demonstrated in FIG. 10 as a sequential diagram. This block diagram finds the corresponding b₀, which is not identifiable with parameter estimation, for each value of b₁ considering the charging sequence. The identified parameters are used to update the observer parameters with the structure of FIG. 6. A pole placement technique is used to assign the observer poles at appropriate values and calculate the corresponding observer gains at each step. The result for the SOC estimation is demonstrated in FIG. 11. Since the initial SOC is known for this test, a coulomb counting method can be used to prepare a benchmark to evaluate the estimation of the observer that starts from an arbitrary initial SOC.

It can be observed from FIG. 11 that the estimated SOC with arbitrarily chosen initial SOC follows the real value for SOC. FIG. 12 shows the error in SOC estimation. It can be observed that most of the time the error is in the acceptable range of 5% except for the time corresponding to the SOC between 0.3 and 0.6. According to Table I, this range is related to segments 4 and 5 with relatively lower fitness criteria.

Despite the inherent nonlinear dynamic of the battery mainly caused by V_{OC}-SOC relationship, a piecewise linear model can be provided for the lithium-polymer battery. The experimental curve for V_{OC}-SOC function may be used to verify this assumption. The linear structure facilitates using the well-developed parameter identification and state estimation techniques in the linear systems to estimate the state of charge of the battery. Moreover, the linear structure of the estimator can be implemented in a battery management system. Applying the estimation approach to the experimental data of the lithium-polymer battery validates the acceptability of the SOC estimation results. On the other side, the piecewise linear model for the battery has the drawback of approximation error regarding the fact that V_{OC}-SOC function is not really linear. The increase in estimation error for the nonlinear segments implies the sensitivity of the approach to nonlinearity error.

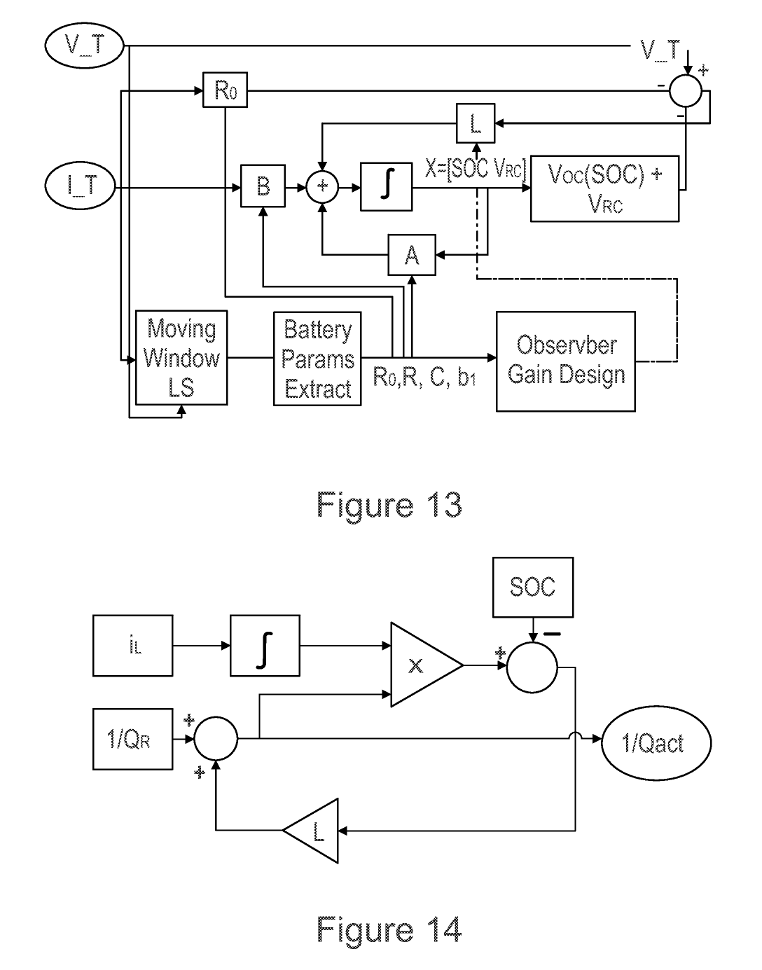

Referring again to FIG. 5, the battery dynamic may be modeled with an RC equivalent that includes one RC pair. A look-up table obtained from experimental data may be used to represent the OCV-SOC relationship. Relying on the fact that the operating point's moving on the OCV-SOC curve may be slow due to the large capacitor of the battery compared to the normal C-rates, a piecewise linear relationship between OCV and SOC at the operating point may be considered. It may also be assumed that the terminal current (i_{L}) and voltage (v_{T}) are the only two values that are accessible from the system modeled by FIG. 13 and Equation (2). To obtain the estimated SOC as one of the states, the parameters in the system can be identified. As set forth herein, it may be presupposed that Q_{R} is the nominal capacity of the battery and accordingly estimate {b₀, R,C,R₀,b₁,S_{oc},V_{RC}} as {\hat{b}₀, \hat{R}, Ĉ, \hat{R}₀, \hat{b}₁, Ŝ_{oc}, \hat{V}_{R}} using system parameter identification methods and state estimation. The aging effect that can be calendar and/or cycling effect may degrade the actual capacity of the battery. As demonstrated herein, keeping the nominal capacity, Q_{R}, instead of the actual capacity, Qact, in the equations of the battery may not degrade the identification results of the other parameters.

### Mathematical Analysis

### Battery Parameter Identification

The transfer function form of the system modeled by FIG. 13 and Equation (2) may be represented as:

$$\begin{matrix}\frac{Y ( s ) - {b}_{0}}{U ( s )} = \frac{{R}_{0} {s}^{2} + ( \frac{{b}_{1}}{{Q}_{act}} + \frac{1}{C} + \frac{{R}_{0}}{RC} ) s + \frac{{b}_{1}}{{RCQ}_{act}}}{s ( s + \frac{1}{RC} )} \\ = \frac{{b}_{00} {s}^{2} + {b}_{11} s + {b}_{22}}{{s}^{2} + {a}_{11} s + {a}_{22}} .\end{matrix} \qquad ( 11 )$$

From transfer function (11) and using bilinear transform

$$( S \to \frac{2}{T} \frac{z - 1}{z + 1} ) ,$$

the discrete transfer function of system (2) with sample time T is obtained:

$$\frac{Y ( {z}^{- 1} ) - {b}_{0}}{U ( {z}^{- 1} )} = \frac{{c}_{0} + {c}_{1} {z}^{- 1} + {c}_{2} {z}^{- 2}}{1 + {a}_{1} {z}^{- 1} + {a}_{2} {z}^{- 2}} . \qquad ( 12 )$$

In order to identify the parameters of a linear system like Equation (12), the relationship between the system's input/output (I/O) samples is described by a standard structure, such as the autoregressive exogenous model (ARX) model:

A(q)y(q)=B(q)u(q)+e(q), (13)

where

A(q)=1+a₁q⁻¹+ . . . aₙq⁻ⁿ, (14)

B(q)=b₀+b₁q⁻¹+ . . . +bₘq^{-m} (15)

and e(q) is white noise (zero mean Gaussian noise). The LS identification approach provides a formula to minimize the Least Square (LS) error between this estimated output value and the real output at the present step. Since the I/O samples are being updated step-by-step while the system is running, a recursive least square (RLS) algorithm can be defined to identify the parameters of the system iteratively. Furthermore, because implementing the RLS algorithm is not easy in a real system and the I/O signal needs to be persistently exciting (PE) at each step, the moving-window LS (MWLS) method may be used, which is more practical. In this approach, the I/O data corresponding to a certain number (window) of past steps is used to estimate the parameters. Identifying the coefficients of the discrete transfer function (12), the reverse bilinear transform

$$( Z \to \frac{2 + sT}{2 - sT} )$$

is used to find the coefficients of the continuous-time transfer function (11). Therefore, assuming that the coefficients {b₀₀, b₁₁, b₂₂, a₁₁, a₂₂} have been identified correctly using the I/O data, the battery parameters may be extracted from the transfer function (11) coefficients as shown in equations 16-20.

$$\begin{matrix}{R}_{0} = {b}_{00} & ( 16 ) \\ RC = \frac{1}{{a}_{11}} & ( 17 ) \\ {b}_{1} = {Q}_{act} RC {b}_{22} & ( 18 ) \\ \begin{matrix}\frac{1}{C} = {b}_{11} - \frac{{R}_{0}}{RC} - \frac{{b}_{1}}{{Q}_{act}} \\ = {b}_{11} - \frac{{R}_{0}}{RC} - RC {b}_{22}\end{matrix} & ( 19 ) \\ R = \frac{RC}{C} & ( 20 )\end{matrix}$$

While R₀ and RC are not dependent on Q_{act} in Equations (16) and (17), Equation (18) shows that b₁ cannot be determined without an accurate approximation of Q_{act}. Therefore, if there is a difference between Q_{act} and Q_{R}, the estimation of the b₁ may indicate the error. Nonetheless, when we use the non-accurate estimated b₁ to estimate C and R, as demonstrated in equations (17) and (18), respectively, the Q_{act} is cancelled out and the estimated results do not depend on the Q_{act}. To conclude, all the battery parameters except for b₁ can be identified uniquely without knowing the actual capacity of the battery. Since we use the OCV-SOC look-up table instead of the identified value of b₁ in SOC estimation algorithm, the estimated b₁ does not affect the estimation results.

### SOC Estimation

After identifying the parameters of the battery, an observer may be used to estimate the SOC, which is one of the states of the model. Assuming that the battery's parameters {R, C, R₀, b₁, b₀} can be estimated as {\hat{R}, Ĉ, \hat{R}₀, \hat{b}₁, \hat{b}₀} the battery model is represented as a system with Equation (21):

$$\{ \begin{matrix}\dot{x} = Ax + Bu \\ y = Cx + Du + {b}_{0} ,\end{matrix} \\ where , \\ {x}_{1} = {S}_{oc} , \\ {x}_{2} = {V}_{RC} , \\ A = [ \begin{matrix}0 & 0 \\ 0 & - \frac{1}{RC}\end{matrix} ] , \\ B = [ \begin{matrix}1 / {Q}_{R} \\ 1 / C\end{matrix} ] , \\ C = [ \begin{matrix}{b}_{1} & 1\end{matrix} ] , \\ D = {R}_{0} , \\ u = {I}_{L} , \\ y = {V}_{T} , \\ x = [ \begin{matrix}{x}_{1} \\ {x}_{2}\end{matrix} ] \qquad ( 21 )$$

Therefore, the observer can be designed as a system with the Equation (22):

$$\{ \begin{matrix}\dot{\hat{x}} = A \hat{x} + Bu + L ( y - \hat{y} ) \\ \hat{y} = C \hat{x} + Du + {b}_{0} ,\end{matrix} \qquad ( 22 )$$

where L^{T}=[L₁ L₂] is the observer gain vector. A linear quadratic (LQ) approach may be used to design an optimal observer that minimizes the error and effort. In this method, the P matrix may be calculated by solving the LQ Riccati equation (23),

AP+P^{T}A−PC^{T}R⁻¹CP=−Q, (23)

where Q and R are arbitrary semi-positive definite and positive definite matrices and the observer gain is obtained from Equation (24),

L^{T}=R⁻¹CP. (24)

FIG. 13 illustrates a block diagram that demonstrates the battery parameters/SOC co-estimation algorithm in accordance with embodiments of the present disclosure. All the battery parameters and the observer gain may be updated in the structure. As shown in FIG. 13, the OCV-SOC function may be used as a look-up table in the structure of the observer instead of using b₀ and b₁. Therefore, b₁ may be used only in designing the observer gain. However, the change in the C matrix caused by different b₁ only affects the optimality of the designed observer from the convergence time and control effort point of view. Moreover, investigating the structure of the observer shows that matrix B also contains the capacity of the battery. If the nominal capacity, Q_{R}, is used instead of the actual capacity, Q_{act}, to build this matrix, it can be shown that it does not influence the estimation of the SOC. That is because in this Luenberger type observer, the error between the actual state and the estimated state, e=\hat{x}−x, the observer error, converges to zero or the observer is asymptotically stable if the matrix A-LC has all negative eigenvalues. Therefore, the convergence of the observer may not depend on the B matrix. Simulation results endorse the fact that considering the nominal capacity instead of the actual capacity in the observer structure does not affect the SOC estimation results.

### Design the Battery Capacity Observer

After estimating the SOC with the parameters/SOC co-estimation method, another observer may be designed for a system that contains the coulomb counting equation to estimate the actual capacity of the battery. In this observer, the changes in the SOC of the battery may ultimately follow the coulomb counting equation in which the capacity is the actual one:

$$S \dot{O} C = \frac{1}{{Q}_{act}} I . \qquad ( 25 )$$

It is shown in the previous section that the estimation of SOC in the presently disclosed method is more based on the OCV of the battery rather than coulomb counting. Therefore, the result of SOC estimation can be used as the measured value to estimate the actual capacity of the battery. The following system may be defined:

$$\{ \begin{matrix}Q ( k + 1 ) = Q ( k ) + w ( k ) \\ SOC ( k + 1 ) = SOC ( k ) + \frac{1}{Q ( k )} {I}_{L} \\ y ( k ) = SOC ( k ) ,\end{matrix} \qquad ( 26 )$$

where Q(k) is the actual capacity of the battery and w(k) is a Gaussian Noise. Since one of the states of the system (26), SOC, can be observed directly from the output data, a reduced order observer (equation (27)) may be designed to estimate the capacity of the battery.

$$\frac{1}{\hat{Q} ( k + 1 )} = \frac{1}{\hat{Q} ( k )} + L ( \hat{y} ( k ) - y ( k ) ) , \qquad ( 27 )$$

where \hat{Q}(k) is the estimated capacity of the battery and y(k) is the estimated output of system (26):

$$\{ \begin{matrix} ( k + 1 ) = ( k ) + \frac{1}{\hat{Q} ( k )} {I}_{L} \\ \hat{y} ( k ) = ( k )\end{matrix} \qquad ( 28 )$$

Since system (28) is nonlinear, instead of linear analytic design methods a trial and error approach may be used to design the observer gain, L. FIG. 14 illustrates a block diagram that implements the battery capacity observer described by equation (27) to estimate the battery capacity. As previously explained, y(t) is the output for system (26) which is SOC of the battery.

### Additional Simulation Results

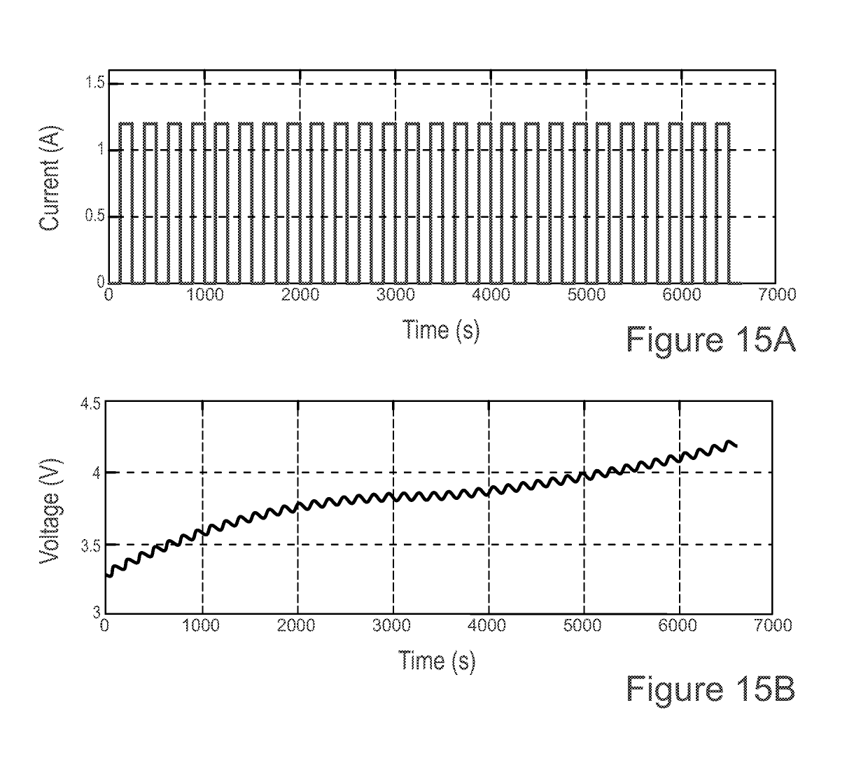

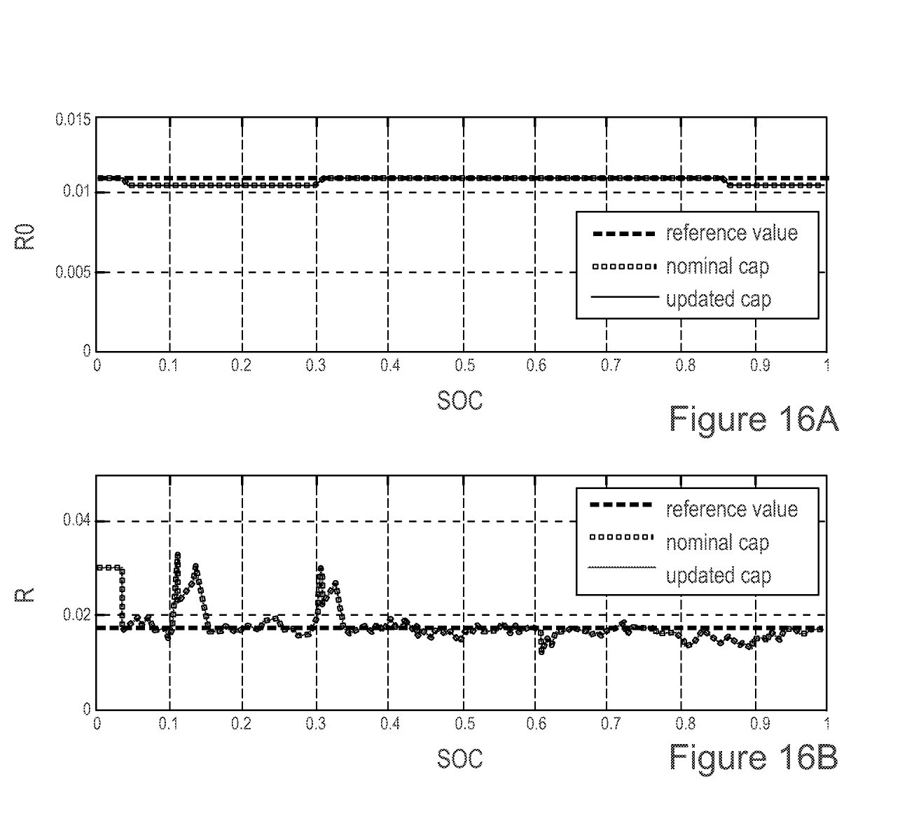

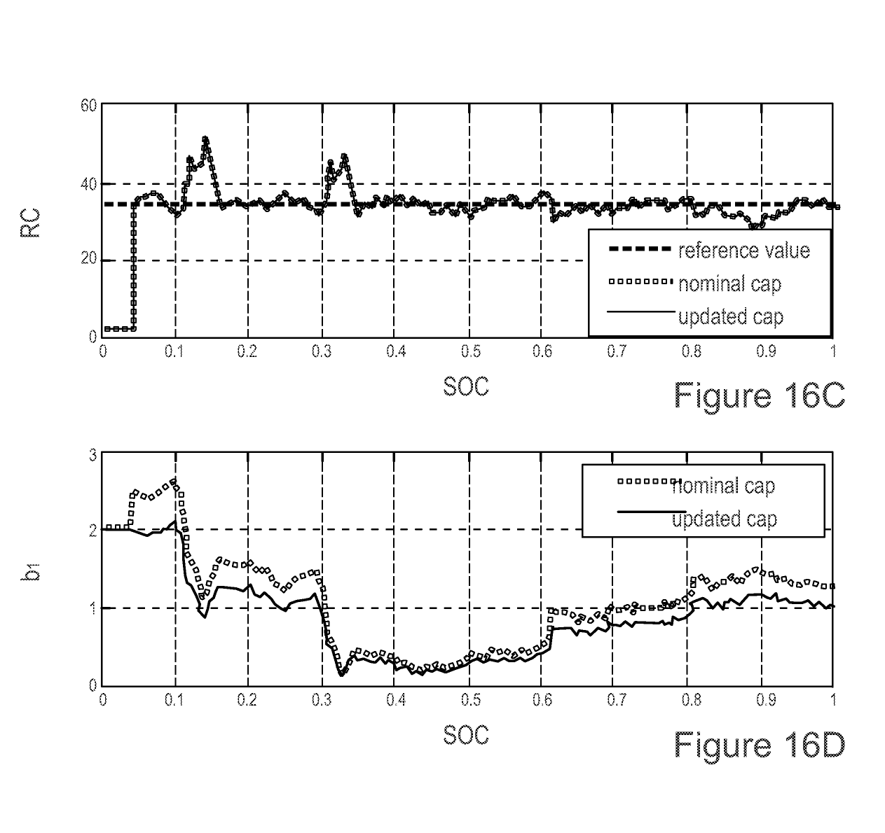

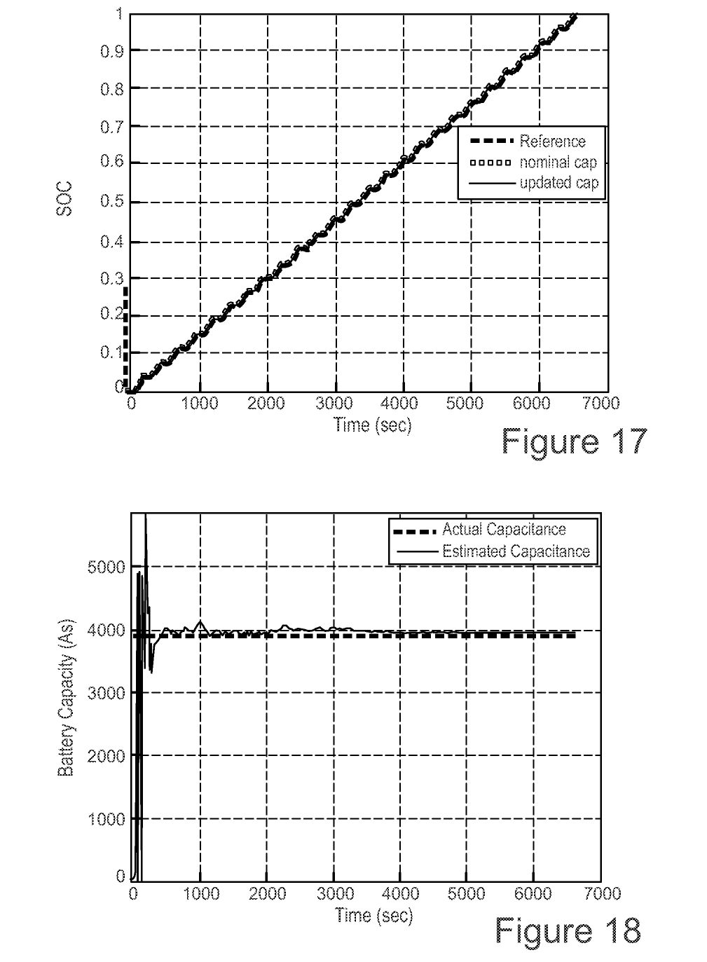

To demonstrate the robustness of the identification and SOC estimation results regarding the uncertainties in the full capacity calculation of the battery, the results may be evaluated using the input/output data from a nonlinear model of the battery. In this model which has been developed in SIMULINK, a look-up table obtained from the experimental data to represent the OCV-SOC function may be used. Also, the battery dynamics are represented by an RC equivalent circuit shown in FIG. 5 with fixed values for R₀, R and C. Although those values change with SOC and C-rate in the real system, they may be kept fixed in this model to make the verification easier. The current and voltage data of the model may be obtained when the capacity of the battery is dropped by 20% of the nominal capacity, which is the extreme capacity degradation for most of the applications. It is similar to getting the current and voltage of a battery that has lost 20% of its capacity due to the cycling ageing effect. However, in the identification algorithm, the nominal capacity is considered as the natural approximation of the full capacity of the battery. Applying the input/output data, demonstrated in FIG. 14, to the parameters identification algorithm, the identified parameters are compared to the results from an algorithm with the actual full capacity. The identification results for both nominal and actual capacities are demonstrated in FIG. 17 with a thicker line for nominal capacity to illuminate the difference. FIGS. 15A and 15B show graphs of current and voltage data obtained from the battery model. FIGS. 16A-16D shows graphs of a comparison of the parameters identification results for nominal and updated capacity nominal and actual capacities. Also, the dotted lines show the reference value for the parameters that have been used in the simulated model. The first three graphs show that R₀, R and RC are identified at the same values for both nominal and actual capacities. These parameters are the major updating factors in the SOC co-estimation structure shown in FIG. 13. On the other side, as expected from Equation 18, FIGS. 16A-16D show that identification of b₁ is significantly affected by the assumption about the battery full capacity. However, following the earlier discussion, it does not influence the SOC estimation results because the experimental look-up table is used in the observer structure instead of b₁. FIG. 17 is a graph showing a comparison of SOC estimations with nominal and updated capacity. The simulation results demonstrated in FIG. 2 confirms that considering the nominal capacity instead of the degraded one does not make any significant difference in the estimation of the SOC. On the contrary, in FIG. 17 the difference between the estimated SOCs with different full capacity considerations slightly increases for the SOCs between 30% and 60%. This is the area in FIGS. 16A-16D that the difference between //the identified bis is minimum compared to other SOCs. Therefore, we can see again that lack of observability has more negative influence on SOC estimation compared to the full capacity error influence. Afterwards, as shown in FIGS. 15A and 15B, when the estimated SOC is applied to the observer in FIG. 14 along with the battery current the parameters/SOC/capacity algorithm is able to accurately estimate the actual capacity of the battery. FIG. 18 is a graph showing capacity estimation compared to the actual capacity of the battery.

### Experimental Results

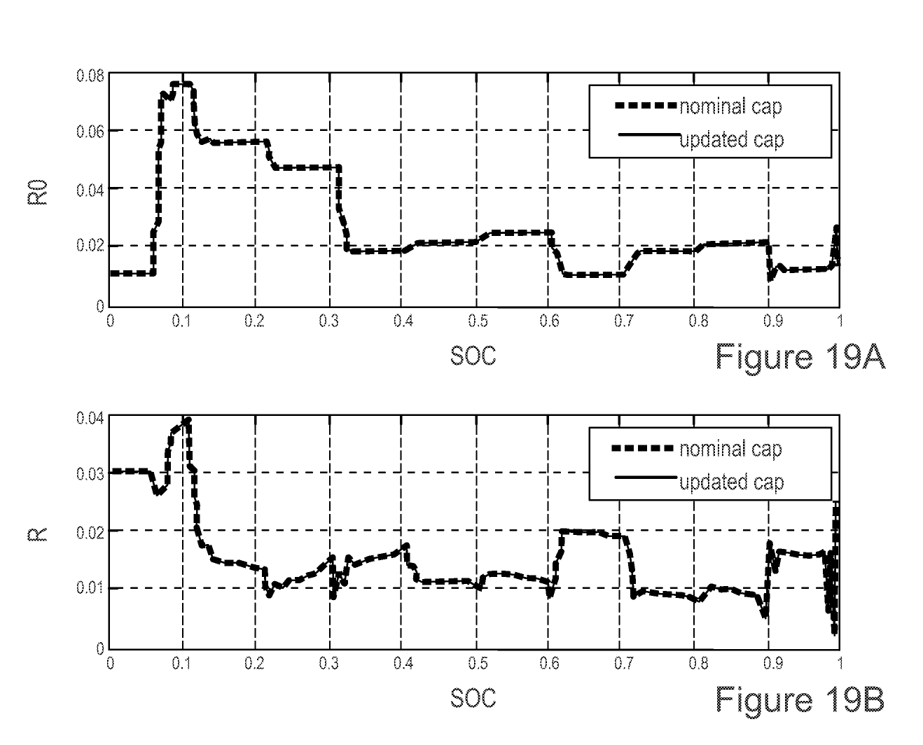

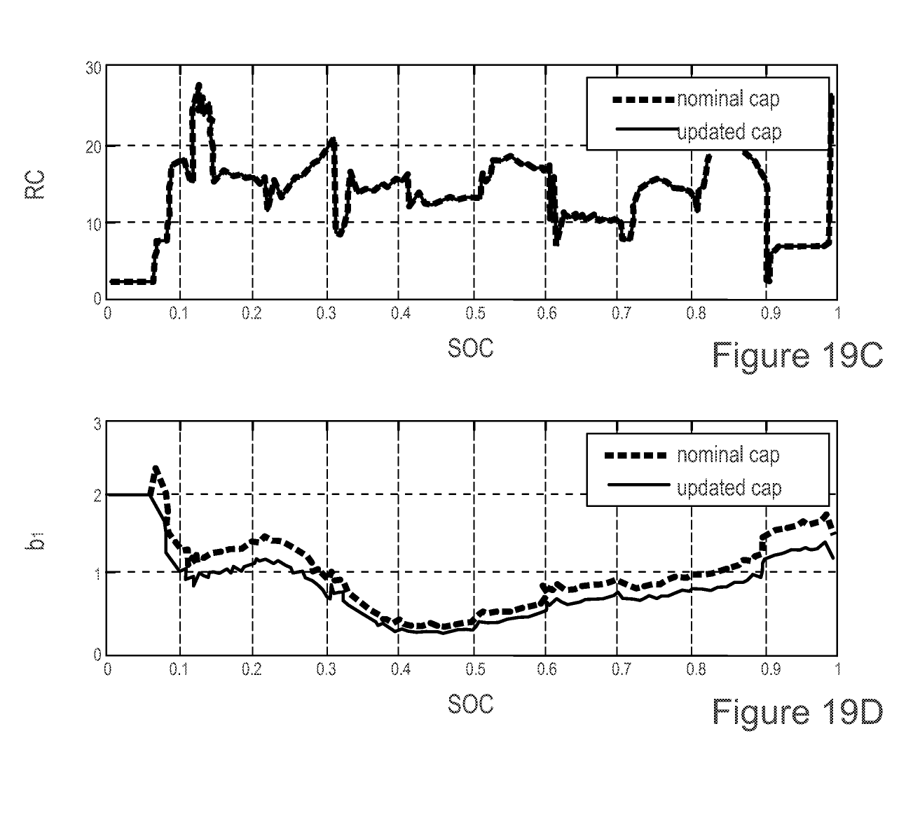

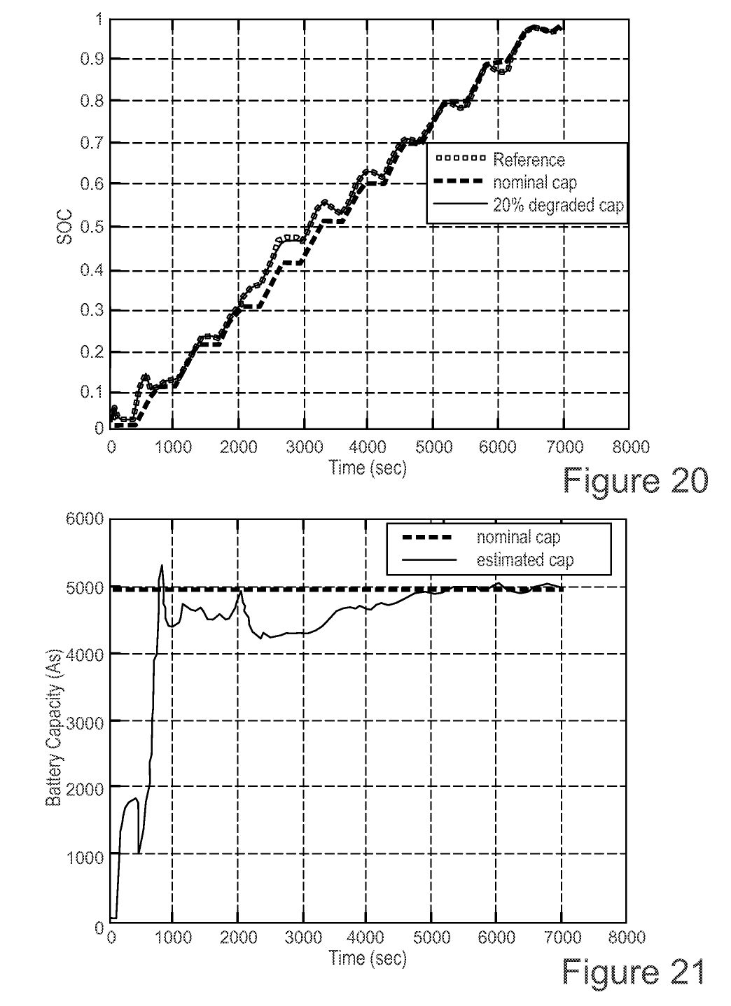

After verifying the performance of the parameters/SOC/capacity co-estimation algorithm using the simulated data, the current and voltage data obtained from the experimental tests on was applied on 1.36 Ah lithium-polymer cells (Kokam SLPB723870H4) to estimate the actual capacity of the cells. In this test, it was assumed that the capacity of the brand new battery is equal to the nominal capacity. Therefore, to evaluate the robustness of the algorithm, this time it was assumed that the full capacity of the battery in the parameters/SOC co-estimation algorithm is considered 20% lower than the nominal capacity. The results of the parameters/SOC co-estimation algorithm were compared for both nominal and 20% degraded capacity in the algorithm structure. The identified parameters in FIGS. 19A-19D shows that even in the experimental case in which the parameters vary with SOC, the wrong assumption about the full capacity of the battery does not deviate the identification of the main parameters, //i.e., R₀, R and C. This figure also shows that b₁ is the only parameter that is identified differently for different assumption about the full capacity. But it does not affect the SOC estimation since look-up table is substituted in the algorithm structure. The SOC estimation results demonstrated in FIG. 20 confirms that considering a wrong value for the capacity does not influence the SOC estimation. Accordingly, the estimated SOC results were used to calculate the actual capacity of the lithium-Polymer battery cell using the online algorithm in FIG. 11. FIG. 21 presents the capacity estimation results compared to the nominal capacity of the battery. This figure shows that although the initial value for the estimated capacity is zero the algorithm is able to compensate the initial state error and estimate the full capacity almost accurately before t=2000 s. The increase in the capacity estimation error between 2000s and 4000s is due to the error in SOC estimation that roots in the observability issue.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as languages for smartphones, Java, Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A method comprising:
determining a terminal current and a terminal voltage of a battery;
maintaining a battery model that defines a relationship between a parameter of the battery, the terminal current, and the terminal voltage; and
determining the parameter of the battery based on the battery model and the acquired terminal current and terminal voltage.

2. The method of claim 1, wherein the parameter comprises a state of charge (SOC) of the battery.

3. The method of claim 1, wherein the parameter comprises a state of health (SOH) of the battery.

4. The method of claim 1, wherein the battery comprises a lithium battery.

5. The method of claim 1, further comprising receiving terminal voltage of the battery,
wherein the battery model defines a relationship between the parameter of the battery and the terminal voltage, and
wherein determining the parameter of the battery comprises determining the parameter of the battery based on the terminal current and the terminal voltage.

6. The method of claim 1, wherein determining the parameter of the battery comprises determining the parameter of the battery during operation of the battery.

7. The method of claim 1, wherein the battery model includes an adaptive co-estimation algorithm.

8. The method of claim 1, wherein the battery model is defined by the equation:
$$S \dot{O} C = \frac{1}{{Q}_{R}} {i}_{L} + L ( f ( SOC ) - {V}_{OC} )$$
wherein Q_{R} is a nominal capacity of the battery, i_{L} is the terminal current, L is a gain, and f(SOC) is a look-up table for battery open circuit voltage and SOC.

9. The method of claim 8, wherein the look-up table includes experimental data.

10. A system comprising:
at least one processor and memory configured to:
determine a terminal current and a terminal voltage of a battery;
maintain a battery model that defines a relationship between a parameter of the battery, the terminal current, and the terminal voltage; and
determine the parameter of the battery based on the battery model and the acquired terminal current and terminal voltage.

11. The system of claim 10, wherein the parameter comprises a state of charge (SOC) of the battery.

12. The system of claim 10, wherein the parameter comprises a state of health (SOH) of the battery.

13. The system of claim 10, wherein the battery comprises a lithium battery.

14. The system of claim 10, wherein the at least one processor and memory are configured to receive a terminal voltage and a terminal current of the battery,
wherein the battery model defines a relationship between the parameter of the battery and the terminal voltage, and
wherein the at least one processor and memory are configured to determine the parameter of the battery based on the terminal voltage.

15. The system of claim 10, the at least one processor and memory are configured to determine the parameter of the battery during operation of the battery.

16. The system of claim 10, wherein the battery model includes an adaptive co-estimation algorithm.

17. The system of claim 10, wherein the battery model is defined by the equation:
$$S \dot{O} C = \frac{1}{{Q}_{R}} {i}_{L} + L ( f ( SOC ) - {V}_{OC} )$$
wherein Q_{R} is a nominal capacity of the battery, i_{L} is the terminal current, L is a gain, and f(SOC) is a look-up table for battery open circuit voltage and SOC.

18. The system of claim 17, wherein the look-up table includes experimental data.

19. The system of claim 10, further comprising a battery interface for measuring the terminal current.

20. The system of claim 10, further comprising presenting the parameter of the battery.
